(19) United States
(12) Patent Application Publication
(10) Pub. No.: US 2025/0204166 A1
(43) Pub. Date: Jun. 19, 2025

(54) DISPLAY PANEL AND DISPLAY DEVICE

(71) Applicant: HKC CORPORATION LIMITED, SHENZHEN (CN)

(72) Inventors: Qin LIANG, SHENZHEN (CN); Yangling TANG, SHENZHEN (CN); Zhisheng XIE, SHENZHEN (CN); Chenchen JIANG, SHENZHEN (CN); Zhi YANG, SHENZHEN (CN); Lidan YE, SHENZHEN (CN)

(73) Assignee: HKC CORPORATION LIMITED, SHENZHEN (CN)

(21) Appl. No.: 18/969,344

(22) Filed: Dec. 5, 2024

(30) Foreign Application Priority Data
Dec. 19, 2023 (CN) 202311763253.X

(51) Int. Cl. H10K 59/122; H10K 59/131

(52) U.S. Cl. CPC H10K 59/122; H10K 59/131

(57) ABSTRACT

A display panel and an electronic device. The display panel includes: a substrate; a plurality of pixel islands, arranged on a side of the substrate; wherein each pixel island comprises at least one sub-pixel; and a plurality of blocking structures; wherein each blocking structure is disposed protruding from the substrate and encloses to form a blocking region; each blocking structure includes a substrate substance filled with spherical particles. A positive projection of each pixel island on the substrate is disposed within a positive projection of a corresponding blocking region on the substrate.

### CROSS REFERENCE

The present disclosure claims priority of Chinese Patent Application No. 202311763253.X, filed on Dec. 19, 2023, the entire contents of which are hereby incorporated by reference in their entirety.

### TECHNICAL FIELD

The present disclosure relates to the field of display technologies, and more specifically to a display panel and a display device.

### BACKGROUND

Stretchable display technology enables a display screen to be stretched in all directions like a rubber band, so as to change shape and be adapted to any surface shape. A stretchable screen can be flexibly applied in a variety of fields, such as consumer electronics, public display, medical, biological, wearable, gaming, fashion, and automotive scenarios, etc.

A stretchable pixel generally includes an island-shaped light-emitting region and a bridge-shaped alignment region. The deformation ability of the alignment region is generally improved by designing curved alignments, and the island-shaped light-emitting region is required to be less affected when subjected to deformation.

### SUMMARY OF THE DISCLOSURE

A display panel, including: a substrate; a plurality of pixel islands, arranged on a side of the substrate; wherein each pixel island includes at least one sub-pixel; and a plurality of blocking structures; wherein each blocking structure is disposed protruding from the substrate and encloses to form a blocking region; each blocking structure includes a substrate substance filled with spherical particles; wherein a positive projection of each pixel island on the substrate is disposed within a positive projection of a corresponding blocking region on the substrate.

An electronic device, including the display panel as above.

### BRIEF DESCRIPTION OF THE DRAWINGS

In order to more clearly illustrate the technical solutions in the embodiments of the present disclosure, the accompanying drawings to be used in the description of the embodiments will be briefly introduced below, and it will be obvious that the accompanying drawings in the following description are only some of the embodiments of the present disclosure, and other accompanying drawings can be obtained according to these drawings for the those skilled in the art, without any creative labor.

FIG. 1 is a top structural schematic view of a display panel according to some embodiments of the present disclosure.

FIG. 2 is a structural schematic view of a longitudinal cross-section of a display panel according to a first implementation of the present disclosure.

FIG. 3 is a structural schematic view of a longitudinal cross-section of a display panel according to a second implementation of the present disclosure.

FIG. 4 is a structural schematic view of a longitudinal cross-section of a display panel according to a third implementation of the present disclosure.

FIG. 5 is a structural schematic view of a longitudinal cross-section of a display panel according to a fourth implementation of the present disclosure.

FIG. 6 is a structural schematic view of a longitudinal cross-section of a display panel according to a fifth implementation of the present disclosure.

### DETAILED DESCRIPTION

The following description, in conjunction with the accompanying drawings of the specification, provides a detailed description of the program of embodiments of the present disclosure.

In the following description, specific details such as particular system structures, interfaces, techniques, and the like are presented for the purpose of illustration and not for limitation, in order to provide a thorough understanding of the present disclosure.

The technical solutions in the embodiments of the present disclosure will be clearly and completely described below in conjunction with the accompanying drawings in the embodiments of the present disclosure, and it is clear that the described embodiments are only a part of the embodiments of the present disclosure, and not all of the embodiments. Based on the embodiments in the present disclosure, all other embodiments obtained by those skilled in the art without creative labor fall within the scope of the present disclosure.

The terms of “first”, “second”, and “third” in the present disclosure are intended for descriptive purposes only, and are not to be construed as indicating or implying relative importance or implicitly specifying the number of technical features indicated. Thus, a feature defined with “first”, “second”, “third” may include at least one such feature, either explicitly or implicitly. In the description of the present disclosure, “plurality” means at least two, e.g., two, three, etc., unless otherwise expressly and specifically limited. All directional indications (e.g., up, down, left, right, forward, backward . . . ) in the embodiments of the present disclosure are only intended to explain the relative positional relationship, movement, etc. between components in a particular attitude (as shown in the accompanying drawings), and the directional indications are changed accordingly if the particular attitude is changed. Furthermore, the terms “including” and “having” and any variations thereof are intended to cover non-exclusive inclusion. For example, a process, method, system, product or apparatus comprising a series of steps or units is not limited to the listed steps or units, but optionally further includes steps or units that are not listed, or optionally includes other steps or units that are inherent to the process, method, product or apparatus.

Reference to “embodiments” herein means that particular features, structures, or characteristics described in conjunction with the embodiments may be included in at least one embodiment of the present disclosure. The presence of the phrase at various points in the specification does not necessarily refer to the same embodiments or to separate or alternative embodiments that are mutually exclusive of other embodiments. It is understood by those skilled in the art, both explicitly and implicitly, that the embodiments described herein may be combined with other embodiments.

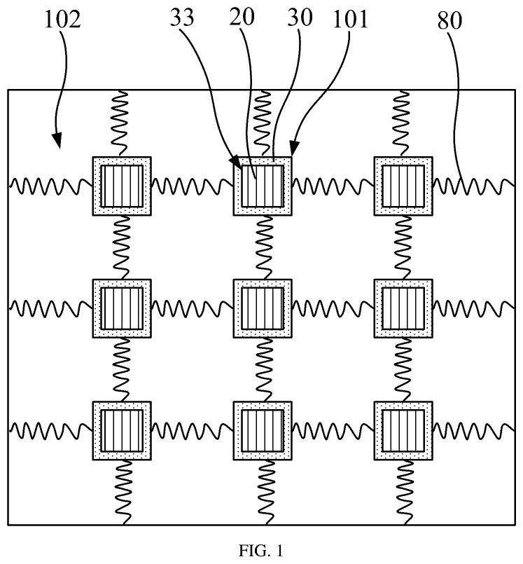

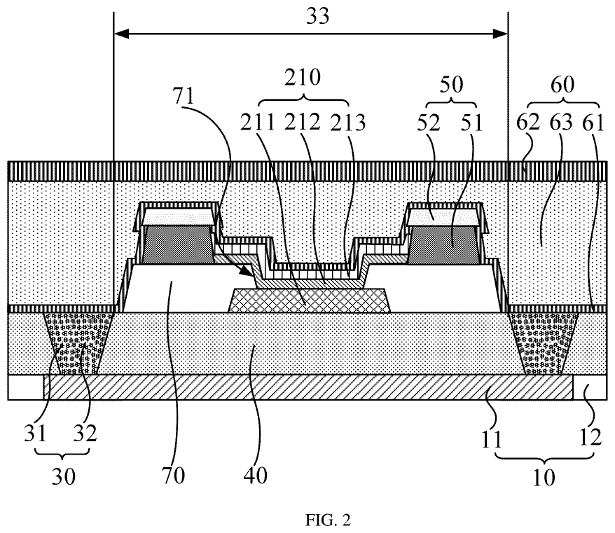

Referring to FIGS. 1 and 2, FIG. 1 is a top structural schematic view of a display panel according to some embodiments of the present disclosure, and FIG. 2 is a structural schematic view of a longitudinal cross-section of a display panel according to a first implementation of the present disclosure.

The present disclosure provides a display panel. The display panel includes a stretchable display panel. The display panel includes a substrate 10, multiple pixel islands 20, and multiple blocking structures 30. The multiple pixel islands 20 are arranged on a side of the substrate 10. Each pixel island 20 includes at least one sub-pixel 210. Each blocking structure 30 is disposed protruding from the substrate 10 and encloses to form a blocking region 33. The blocking structure 30 includes a substrate substance 32 filled with spherical particles 31. A positive projection of each pixel island 20 on the substrate 10 is disposed within a positive projection of a corresponding blocking region 33 on the substrate 10.

In the present disclosure, the positive projection of the pixel island 20 on the substrate 10 is within the positive projection of the blocking region 33 on the substrate 10, such that the blocking structure 30 is disposed around the pixel island 20, thereby reducing the effect of stretching or compression on the pixel island 20 when the display panel is stretched or compressed, so as to reduce the deformation of the sub-pixel 210 and thus enhance the display effect of the display panel. In addition, the blocking structure 30 includes the substrate substance 32 filled with the spherical particles 31 of the substrate substance 32, which may enhance the strength of the blocking structure 30 and reduce the effect of stretching or compression on the pixel islands 20, and further, when the blocking structure 30 is subjected to stretching or compression, the mutual movement of the spherical particles 31 is conducive to dispersing the deformation stresses and further reduces the effect of stretching or compression on the pixel island 20.

The material and thickness of the substrate 10 are not limited herein and can be selected according to actual needs.

In the embodiments, the display panel has an island region 101 and a stretching region 102 disposed on a side edge of the island region 101. The substrate 10 includes a flexible substrate plate 12 and a rigid substrate plate 11. The flexible substrate plate 12 is disposed in the stretching region 102, and the rigid substrate plate 11 is disposed in the island region 101.

The pixel island 20 is disposed in the island region 101. The pixel island 20 may include one sub-pixel 210 or multiple sub-pixels 210. The arrangement of the sub-pixels 210 is not limited herein and can be selected according to actual needs.

One sub-pixel 210 corresponds to a color, and herein there is no restriction on the color corresponding to the sub-pixel 210. Further, the shape and size of the sub-pixel 210 are limited and can bee selected according to actual needs. The sub-pixel 210 includes an anode 211, a light-emitting layer 212, and a cathode 213 sequentially cascaded towards a direction away from the substrate 10. Specifically, the sub-pixel 210 includes an Organic Light-Emitting Diode (OLED).

In the illustrated embodiments, the pixel islands 20 are arranged in a matrix. Each pixel island 20 includes one sub-pixel 210.

The positive projection of the pixel island 20 on the substrate 10 is disposed within the positive projection of the blocking region 33 on the substrate 10, such that the blocking structure 30 is disposed around the pixel island 20 in order to ameliorate the effect of stretching or compression on the pixel island 20 when stretching the display panel, so as to minimize the deformation of the sub-pixel 210 and to enhance the display effect of the display panel.

The blocking structure 30 is arranged at least partially overlapping with the island region 101, or the positive projection of the blocking structure 30 on the substrate 10 is disposed within the stretching region 102.

The present embodiments are mainly illustrated with the blocking structure 30 being disposed in the island region 101 as an example.

The blocking structure 30 includes the substrate substance 32 filled with the spherical particles 31 of the substrate substance 32, which may enhance the strength of the blocking structure 30 and reduce the effect of stretching or compression on the pixel islands 20, and further, when the blocking structure 30 is subjected to stretching or compression, the mutual movement of the spherical particles 31 is conducive to dispersing the deformation stresses and further reduces the effect of stretching or compression on the pixel island 20.

Further, the substrate substance 32 includes an organic material, and the Young's modulus of the substrate substance 32 is less than the Young's modulus of the spherical particles 31, such that the spherical particles 31 can enhance the strength of the blocking structure 30. In addition, each spherical particles 31 is set in a spherical shape, such that when the spherical particles 31 undergo deformation, the deformation stress generated thereof can be uniformly dispersed in the substrate substance 32, thereby reducing the deformation of the blocking structure 30 and thus reducing the effect of stretching or compression on the pixel island 20.

The display panel further includes a flat layer 40 disposed between the substrate 10 and the pixel islands 20. The material and thickness of the flat layer 40 are not limited herein and can be selected according to actual needs. The flat layer 40 covers at least the island region 101.

In the illustrated embodiments, the flat layer 40 covers the island region 101 and the stretching region 102.

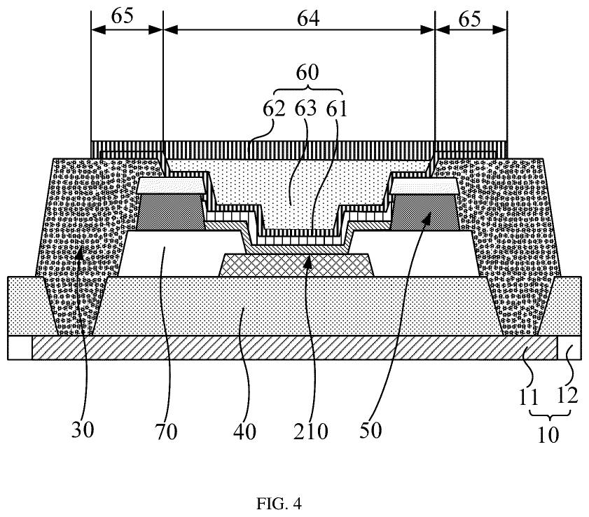

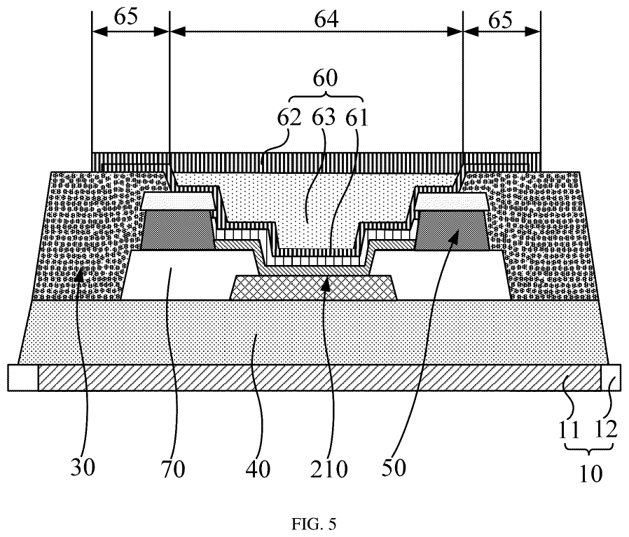

The blocking structure 30 may be wholly embedded in the flat layer 40, or may be at least partially protruding out of a side surface of the flat layer 40 away from the substrate 10. When the blocking structure 30 is arranged at least partially protruding out of the side surface of the flat layer 40 away from the substrate 10, the blocking structure 30 may be partially embedded within the flat layer 40 and partially protruding out of the flat layer 40 (as shown in FIG. 4); alternatively, the blocking structure 30 may be arranged fully protruding out of the flat layer 40 (as shown in FIG. 5).

In the illustrated embodiments, the blocking structure 30 is fully embedded in the flat layer 40 and extends through the flat layer 40 in a direction perpendicular to the substrate 10. The positive projection of the blocking structure 30 on the substrate 10 is disposed within a positive projection of the blocking region 33 on the substrate 10, such that when stretching or compressing the display panel, the blocking structure 30 can serve to reduce the effect of stretching or compression on the pixel island 20 in the direction parallel to the substrate 10.

The display panel further includes a pixel defining layer 70. The pixel defining layer 70 is configured to limit a location of the sub-pixel 210. The pixel definition layer 70 is disposed on a side of the flat layer 40 away from the substrate 10. The pixel definition layer 70 defines multiple pixel openings 71 spaced apart, and each sub-pixel 210 is disposed within a corresponding pixel opening 71.

The pixel defining layer 70 may be at least partially disposed in the island region 101. That is, the pixel defining layer 70 may be partially disposed in the island region 101 and partially disposed in the stretching region 102; alternatively, the pixel defining layer 70 may be wholly disposed in the island region 101. There are no limitations herein with respect to the thickness, the material, and the location of the pixel defining layer 70, which are selected based on actual needs.

In the embodiments, the pixel defining layer 70 is disposed in the island region 101, and a positive projection of the pixel defining layer 70 on the substrate 10 is disposed within the positive projection of the blocking region 33 on the substrate 10.

The display panel further includes an isolation structure 50; the isolation structure 50 encloses the sub-pixel 210 within the pixel island 20 and is electrically connected to the sub-pixel 210 within the pixel island 20; a positive projection of the isolation structure 50 on the substrate 10 is disposed within the positive projection of the blocking region 33 on the substrate 10; and/or, the display panel further includes an encapsulation structure 60; the encapsulation structure 60 is disposed on a side of the pixel island 20 away from the substrate 10, and a positive projection of the encapsulation structure 60 on the substrate 10 covers at least the positive projection of the pixel island 20 on the substrate 10.

It should be noted that the terms of “A and/or B” in the present disclosure indicate that only A is included, or only B is included, or both A and B are included.

In the illustrated embodiments, the display panel includes the isolation structure 50 and the encapsulation structure 60. The isolation structure 50 is configured to isolate the sub-pixel 210 within the pixel island 20, so as to conduct the sub-pixels 210 within the pixel islands 20 to each other. The encapsulation structure 60 is configured to encapsulate the pixel island 20 and serves to isolate the water and oxygen to protect the sub-pixel 210. The positive projection of the encapsulation structure 60 on the substrate 10 covers the entire substrate 10.

Further, the isolation structure 50 is arranged protruding from a side surface of the pixel defining layer 70 away from the substrate 10 and encloses at least one pixel opening 71. One isolation structure 50 encloses at least one pixel opening 71, and there is no limitation herein on the number of pixel openings 71 enclosed by the isolation structure 50, which is selected according to actual needs. In the illustrated embodiments, one isolation structure 50 encloses one sub-pixel 210.

The isolation structure 50 includes an electrically conductive portion 51 and an insulating portion 52 that shields the electrically conductive portion 51; the insulating portion 52 extends out of the electrically conductive portion 51 in a planar direction parallel to the substrate 10. That is, an area of a positive projection of the insulating portion 52 on the substrate 10 is greater than an area of a positive projection of the electrically conductive portion 51 on the substrate 10. The cathode 213 of the sub-pixel 210 is electrically connected to a neighboring electrically conductive portion 51. A vaporization angle of an edge of the insulating portion 52 extending out of the electrically conductive portion 51 during vaporization of the sub-pixel 210 can be adjusted, such that the cathode 213 of the sub-pixel 210 can cover the light-emitting layer 212 of the sub-pixel 210 and achieve a good overlap with the electrically conductive portion 51, thereby achieving a good electrical connection between the sub-pixel 210 and the isolation structure 50.

It should be appreciated that in other embodiments, the isolation structure 50 may be of other structures. For example, the sub-pixel 210 is vaporized through a metal mask plate technology, and the isolation structure 50 only serves to isolate the sub-pixel 210.

In the proposed embodiments, the design of the isolation structure 50 may save cost by omitting the metal mask plate when vaporizing the sub-pixels 210. In addition, when there are multiple sub-pixels 210 arranged within the pixel island 20, the structural design of the isolation structure 50 may further reduce the spacing between the sub-pixels 210 within the pixel island 20, thereby enhancing the pixel opening rate.

The encapsulation structure 60 includes a first encapsulation layer 61, a second encapsulation layer 62, and a filler layer 63 disposed between the first encapsulation layer 61 and the second encapsulation layer 62. The first encapsulation structure 60 is disposed on a side of the filler layer 63 near the substrate 10. The first encapsulation layer 61 covers the flat layer 40 and the blocking structure 30. Each of the first encapsulation layer 61 and the second encapsulation layer 62 includes an inorganic material. Specifically, the inorganic material includes at least one of silicon nitride, silicon oxide, and silicon nitride oxide.

As shown in FIG. 1, the display panel further includes a connecting bridge 80; the connecting bridge 80 is disposed between two adjacent pixel islands 20 and is configured to electrically connect the two adjacent pixel islands 20. The connecting bridge 80 is disposed in the stretching region 102. The material of the connecting bridge 80 is not limited herein and can be selected according to actual needs.

In the illustrated embodiment, the connecting bridge 80 may be of an S-shaped alignment, and in other embodiments, the connecting bridge 80 may be of other structures.

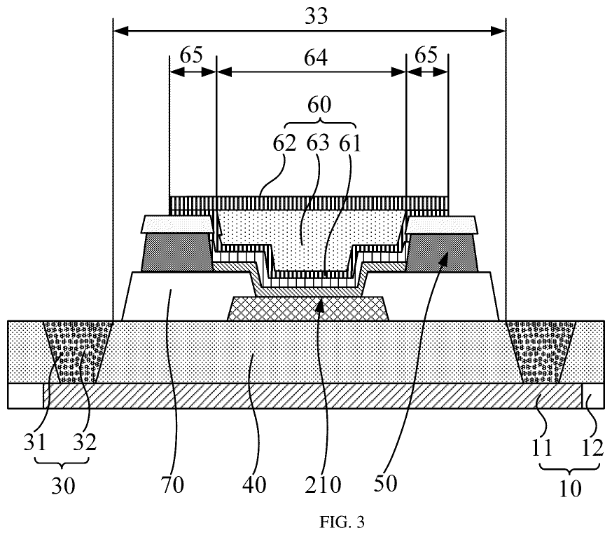

Referring to FIGS. 2 and 3, FIG. 3 is a structural schematic view of a longitudinal cross- section of a display panel according to a second implementation of the present disclosure.

The second implementation of the display panel provided in the present disclosure has a substantially similar structure to the first implementation of the display panel provided in the present disclosure, with the difference that the display panel includes multiple encapsulation structures 60 independently disposed of each other.

In the embodiments, the display panel includes multiple encapsulation structures 60 independently disposed of each other; each encapsulation structure 60 is disposed on a side of the pixel island 20 away from the substrate 10 and in a one-to-one correspondence with the pixel islands 20. The encapsulation structure 60 covers the pixel island 20 and extends to the blocking structure 30 to cover a portion of a side surface of the blocking structure 30 away from the substrate 10.

The encapsulation structure 60 is disposed in the island region 101. The encapsulation structure 60 includes a first encapsulation layer 61, a second encapsulation layer 62, and a filler layer 63 disposed between the first encapsulation layer 61 and the second encapsulation layer 62. The first encapsulation structure 60 is disposed on a side of the filler layer 63 near the substrate 10. The encapsulation structure 60 includes a first portion 64 and a second portion 65 that are interconnected; the first portion 64 includes a portion of the first encapsulation layer 61, a portion of the second encapsulation layer 62, and the filler layer 63 that are disposed in a sequential cascade, and the second portion 65 includes a portion of the first encapsulation layer 61 and a portion of the second encapsulation layer 62 that are disposed in a sequential cascade. The first portion 64 covers the sub- pixel 210. The second portion 65 covers at least a portion of the isolation structure 50.

Considering that the first encapsulation layer 61 and the second encapsulation layer 62 both include inorganic materials, and that the inorganic materials have poor bending resistance, the encapsulation structures 60 in the embodiments are disposed in the island regions 101 and independently of each other, and each is designed to correspond to a pixel island 20, which not only serves to encapsulate the pixel island 20, but also reduces the overall thickness of the encapsulation structure 60. In this way, the risk of fracture of the encapsulation layer in the encapsulation structure 60 may be reduced, thereby enhancing the deformation resistance of the stretching region 102.

Compared to the first implementation of the display panel provided in the present disclosure, the present implementation may likewise reduce the effect of stretching or compression on the pixel island 20 when the display panel is stretched or compressed, so as to reduce the deformation of the sub-pixels 210 and enhance the display effect of the display panel. In addition, compared to the first implementation of the display panel provided in the present disclosure, the present implementation may further reduce the risk of fracture of the encapsulation layer in the encapsulation structure 60, so as to enhance the deformation resistance of the stretching region 102.

Referring to FIGS. 2 and 4, FIG. 4 is a structural schematic view of a longitudinal cross- section of a display panel according to a third implementation of the present disclosure.

The third implementation of the display panel provided in the present disclosure has a substantially similar structure to the second implementation of the display panel provided in the present disclosure, with the difference that the blocking structure 30 may be partially embedded in the flat layer 40 and partially protruding from the flat layer 40.

In the embodiments, the blocking structure 30 is arranged partially protruding from a side surface of the flat layer 40 away from the substrate 10, and encloses the pixel island 20. Specifically, a portion of the blocking structure 30 is embedded in the flat layer 40, and the other portion of the blocking structure 30 is arranged protruding from the flat layer 40. The blocking structure 30 further encloses the corresponding pixel defining layer 70.

It should be understood that in other embodiments, the blocking structure 30 may be arranged passing through the pixel defining layer 70 in the direction perpendicular to the substrate 10.

The side surface of the blocking structure 30 away from the substrate 10 is flush with a side surface of the filler layer 63 away from the substrate 10, or the side surface of the blocking structure 30 away from the substrate 10 is slightly higher than the side surface of the filler layer 63 away from the substrate 10, thereby ensuring that a portion of the first encapsulation layer 61 and a portion of the second encapsulation layer 62 in the first portion 65 may be contacted to seal the filler layer 63 between the first encapsulation layer 61 and the second encapsulation layer 62. In this way, the mutually independent encapsulation structures 60 are realized, thereby reducing the overall thickness of the encapsulation structures 60.

Further, the blocking structure 30 encloses the isolation structure 50. An inner sidewall of the blocking structure 30 is in contact with a side wall of a neighboring isolation structure 50, and the blocking structure 30 covers a portion of a side surface of the isolation structure 50 away from the substrate 10. The encapsulation structure 60 covers the pixel island 20 and extends to the blocking structure 30 to covers a portion of the side surface of the blocking structure 30 away from the substrate 10.

Specifically, the first portion 64 of the encapsulation structure 60 covers the sub-pixel 210 as well as a portion of the isolation structure 50, and the second portion 65 of the encapsulation structure 60 extends to the blocking structure 30 and covers a portion of the surface of the blocking structure 30.

It should be understood that the greater the height of the blocking structure 30 protruding from the surface of the flat layer 40 in the direction perpendicular to the substrate 10, the greater the ability of the blocking structure 30 to reduce the effects of stretching and compression on the pixel island 20.

That is, compared to the second implementation of the display panel provided in the present disclosure, the ability of the blocking structure 30 in the present embodiments to reduce the effect of stretching and compression on the pixel islands 20 may be stronger.

Referring to FIGS. 2 and 5, FIG. 5 is a structural schematic view of a longitudinal cross- section of a display panel according to a fourth implementation of the present disclosure.

The fourth implementation of the display panel provided in the present disclosure has a substantially similar structure to the third implementation of the display panel provided in the present disclosure, with the difference that the blocking structure 30 may be arranged all protruding from the flat layer 40.

In the embodiments, the blocking structure 30 is arranged all protruding from the flat layer 40, and the flat layer 40 is disposed in the island region 101.

In the embodiments, the flat layer 40 is disposed in the island region 101, which makes the stretching region 102 have better deformation ability. Further, the present embodiments can likewise reduce the effect of stretching or compression on the pixel island 20 when the display panel is stretched or compressed, so as to reduce the deformation of the sub-pixels 210 and enhance the display effect of the display panel.

It should be understood that in other embodiments, the flat layer 40 may cover the island region 101 and the stretching region 102.

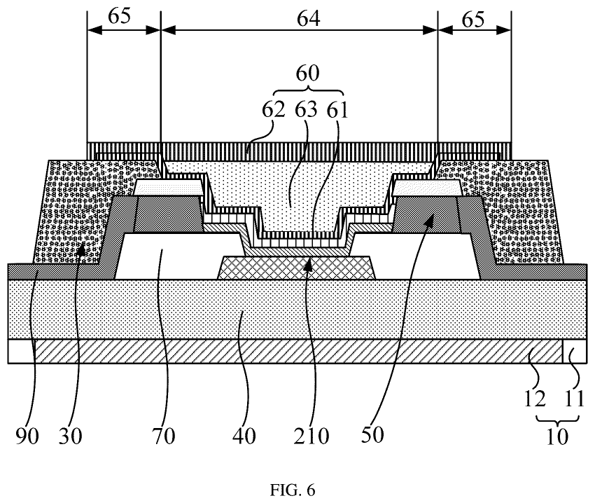

Referring to FIGS. 2 and 6, FIG. 6 is a structural schematic view of a longitudinal cross- section of a display panel according to a fifth implementation of the present disclosure.

The fifth implementation of the display panel provided by the present disclosure has a substantially similar structure to the fourth implementation of the display panel provided by the present disclosure, with the difference that the display panel further includes a connecting lead 90 disposed between the blocking structure 30 and the flat layer 40; an end of the connecting lead 90 is electrically connected to the cathode 213 of the sub-pixel 210 within the pixel island 20 through the isolation structure 50, and the other end of the connecting lead 90 is electrically connected to a neighboring connecting bridge 80.

In the embodiments, the connecting bridge 80 is disposed between two neighboring pixel islands 20 and is configured to electrically connect the cathodes 213 of the sub-pixels 210 in the two neighboring pixel islands 20.

The display panel further includes the connecting lead 90, and the connecting lead 90 is disposed between the blocking structure 30 and the flat layer 40; an end of the connecting lead 90 is electrically connected to the cathode 213 of the sub-pixel 210 in the pixel island 20 through the isolation structure 50, and the other end is electrically connected to the neighboring connecting bridge 80.

Specifically, an end of the connecting lead 90 is connected to the electrically conductive portion 51 of the isolation structure 50 and the other end of the connecting lead 90 is electrically connected to the neighboring connecting bridge 80. The material of the connecting lead 90 may be the same as or different from the material of the electrically conductive portion 51 of the isolation structure 50.

In the embodiments, the connecting lead 90 is patterned and formed with the same conductive material as the isolation structure 50, which may simplify the preparation of the display panel.

The present embodiments can likewise reduce the effect of stretching or compression on the pixel island 20 when the display panel is stretched or compressed, so as to reduce the deformation of the sub-pixels 210 and enhance the display effect of the display panel.

The present disclosure provides a display device, including the display panel as described above.

In the above embodiments, the description of each embodiment has its own focus, and the parts that are not detailed in a certain embodiment can be seen in the relevant descriptions of other embodiments.

The above is only some embodiments of the present disclosure, and is not intended to limit the scope of the present disclosure. Any equivalent structure or equivalent process transformation utilizing the contents of the specification of the present disclosure and the accompanying drawings, or directly or indirectly utilized in other related technical fields, are all reasonably included in the scope of the present disclosure.

Claims what is claimed is:

1. A display panel, comprising:
a substrate;
a plurality of pixel islands, arranged on a side of the substrate; wherein each pixel island comprises at least one sub-pixel; and
a plurality of blocking structures; wherein each blocking structure is disposed protruding from the substrate and encloses to form a blocking region; each blocking structure comprises a substrate substance filled with spherical particles;
wherein a positive projection of each pixel island on the substrate is disposed within a positive projection of a corresponding blocking region on the substrate.

2. The display panel according to claim 1, further comprising a flat layer disposed between the substrate and the plurality of pixel islands; wherein each blocking structure is wholly embedded in the flat layer and extends through the flat layer in a direction perpendicular to the substrate; a positive projection of each blocking structure on the substrate is disposed within a positive projection of a corresponding blocking region on the substrate.

3. The display panel according to claim 2, wherein the display panel further comprises an isolation structure; the isolation structure encloses the sub-pixel within a corresponding pixel island and is electrically connected to the sub-pixel within the corresponding pixel island; a positive projection of the isolation structure on the substrate is disposed within a positive projection of a corresponding blocking region on the substrate;
and/or, the display panel further comprises an encapsulation structure; the encapsulation structure is disposed on a side of the pixel island away from the substrate, and a positive projection of the encapsulation structure on the substrate covers at least a positive projection of the corresponding pixel island on the substrate.

4. The display panel according to claim 3, further comprising a pixel defining layer; wherein the pixel definition layer defines a plurality of pixel openings spaced apart, and each sub-pixel is disposed within a corresponding pixel opening;
the isolation structure is arranged protruding from a side surface of the pixel defining layer away from the substrate and encloses a corresponding pixel opening; the isolation structure comprises an electrically conductive portion and an insulating portion that shields the electrically conductive portion;
the insulating portion extends out of the electrically conductive portion in a planar direction parallel to the substrate;
the electrically conductive portion is electrically connected to a cathode of the sub-pixel of a corresponding pixel island adjacent to the electrically conductive portion.

5. The display panel according to claim 1, further comprising a flat layer disposed between the substrate and the plurality of pixel islands; wherein each blocking structure is arranged at least partially protruding out of a side surface of the flat layer away from the substrate and encloses a corresponding pixel island.

6. The display panel according to claim 5, wherein the display panel further comprises an isolation structure; the isolation structure encloses the sub-pixel within a corresponding pixel island and is electrically connected to the sub-pixel within the corresponding pixel island; each blocking structure encloses a corresponding isolation structure; an inner sidewall of the blocking structure is in contact with a side wall of the corresponding isolation structure adjacent to the blocking structure, and the blocking structure covers a portion of a side surface of the corresponding isolation structure away from the substrate.

7. The display panel according to claim 6, further comprising a plurality of encapsulation structures independently disposed of each other; wherein each encapsulation structure is disposed on a side of a corresponding pixel island away from the substrate, and the plurality of encapsulation structures are in a one-to-one correspondence with the plurality of pixel islands; each encapsulation structure covers the corresponding pixel island and extends to a corresponding blocking structure to cover a portion of a side surface of the corresponding blocking structure away from the substrate.

8. The display panel according to claim 6, wherein each encapsulation structure comprises a first encapsulation layer, a second encapsulation layer, and a filler layer disposed between the first encapsulation layer and the second encapsulation layer; the first encapsulation structure is disposed on a side of the filler layer near the substrate; the first encapsulation layer covers the flat layer and the corresponding blocking structure; each of the first encapsulation layer and the second encapsulation layer comprises an inorganic material.

9. The display panel according to claim 6, further comprising a connecting bridge; wherein the connecting bridge is disposed between corresponding adjacent two of the plurality of pixel islands and configured to electrically connect cathodes of the sub-pixels in the adjacent two of the plurality of pixel islands.

10. The display panel according to claim 9, wherein the display panel further comprises a connecting lead, and the connecting lead is disposed between a corresponding blocking structure and the flat layer; an end of the connecting lead is electrically connected to the cathode of the sub-pixel in a corresponding pixel island through a corresponding isolation structure, and the other end of the connecting lead is electrically connected to the corresponding connecting bridge adjacent to the connecting lead.

11. The display panel according to claim 9, wherein the connecting bridge is of an S-shaped alignment.

12. The display panel according to claim 6, further comprising a pixel defining layer; wherein the pixel definition layer defines a plurality of pixel openings spaced apart, and each sub-pixel is disposed within a corresponding pixel opening;
the isolation structure is arranged protruding from a side surface of the pixel defining layer away from the substrate and encloses a corresponding pixel opening; the isolation structure comprises an electrically conductive portion and an insulating portion that shields the electrically conductive portion;
the insulating portion extends out of the electrically conductive portion in a planar direction parallel to the substrate;
the electrically conductive portion is electrically connected to a cathode of the sub-pixel of a corresponding pixel island adjacent to the electrically conductive portion.

13. The display panel according to claim 1, wherein the substrate substance comprises an organic material, and a Young's modulus of the substrate substance is less than a Young's modulus of the spherical particles.

14. The display panel according to claim 1, wherein the display panel has an island region and a stretching region disposed on a side edge of the island region; the substrate comprises a flexible substrate plate and a rigid substrate plate; the flexible substrate plate is disposed in the stretching region, and the rigid substrate plate is disposed in the island region.

15. An electronic device, comprising a display panel;
wherein the display panel comprises:
a substrate;
a plurality of pixel islands, arranged on a side of the substrate; wherein each pixel island comprises at least one sub-pixel; and
a plurality of blocking structures; wherein each blocking structure is disposed protruding from the substrate and encloses to form a blocking region; each blocking structure comprises a substrate substance filled with spherical particles;
wherein a positive projection of each pixel island on the substrate is disposed within a positive projection of a corresponding blocking region on the substrate.

16. The electronic device according to claim 15, wherein the display panel further comprises a flat layer disposed between the substrate and the plurality of pixel islands; wherein each blocking structure is wholly embedded in the flat layer and extends through the flat layer in a direction perpendicular to the substrate; a positive projection of each blocking structure on the substrate is disposed within a positive projection of a corresponding blocking region on the substrate.

17. The electronic device according to claim 16, wherein the display panel further comprises an isolation structure; the isolation structure encloses the sub-pixel within a corresponding pixel island and is electrically connected to the sub-pixel within the corresponding pixel island; a positive projection of the isolation structure on the substrate is disposed within a positive projection of a corresponding blocking region on the substrate;
and/or, the display panel further comprises an encapsulation structure; the encapsulation structure is disposed on a side of the pixel island away from the substrate, and a positive projection of the encapsulation structure on the substrate covers at least a positive projection of the corresponding pixel island on the substrate.

18. The electronic device according to claim 15, further comprising a flat layer disposed between the substrate and the plurality of pixel islands; wherein each blocking structure is arranged at least partially protruding out of a side surface of the flat layer away from the substrate and encloses a corresponding pixel island.

19. The electronic device according to claim 18, wherein the display panel further comprises an isolation structure; the isolation structure encloses the sub-pixel within a corresponding pixel island and is electrically connected to the sub-pixel within the corresponding pixel island; each blocking structure encloses a corresponding isolation structure; an inner sidewall of the blocking structure is in contact with a side wall of the corresponding isolation structure adjacent to the blocking structure, and the blocking structure covers a portion of a side surface of the corresponding isolation structure away from the substrate.

20. The electronic device according to claim 19, further comprising a plurality of encapsulation structures independently disposed of each other; wherein each encapsulation structure is disposed on a side of a corresponding pixel island away from the substrate, and the plurality of encapsulation structures are in a one-to-one correspondence with the plurality of pixel islands; each encapsulation structure covers the corresponding pixel island and extends to a corresponding blocking structure to cover a portion of a side surface of the corresponding blocking structure away from the substrate.
